(19) United States
(12) Patent Application Publication
(10) Pub. No.: US 2014/0175464 A1
(43) Pub. Date: Jun. 26, 2014

(54) LIGHT EMITTING DIODE DEVICE

(71) Applicant: Advanced Optoelectronic Technology, Inc., Hsinchu Hsien (TW)

(72) Inventors: MING-TA TSAI, Hukou (TW); CHUNG-MIN CHANG, Hukou (TW); CHIH-PENG HSU, Hukou (TW)

(73) Assignee: ADVANCED OPTOELECTRONIC TECHNOLOGY, INC., Hsinchu Hsien (TW)

(21) Appl. No.: 13/963,123

(22) Filed: Aug. 9, 2013

(30) Foreign Application Priority Data
Dec. 25, 2012 (CN) 201210569514X

(51) Int. Cl. H01L 33/52

(52) U.S. Cl. CPC H01L 33/52
USPC 257/88

(57) ABSTRACT

A light emitting diode (LED) device includes a light guiding member having a light incident surface, and an LED light bar mounted on the light incident surface. The LED light bar includes a printed circuit board, LEDs mounted on the printed circuit board, and encapsulating layers formed on the printed circuit board and respectively encapsulating the LEDs therein. Each encapsulating layer includes a light outputting surface away from the printed circuit board. The light incident surface faces the light outputting surface and air between the light incident surface and the light outputting surface is entirely exhausted.

### BACKGROUND

1. Technical Field

The present disclosure relates to semiconductor devices and, more particularly, to a light emitting diode device.

2. Description of Related Art

LEDs have many beneficial characteristics, including low electrical power consumption, low heat generation, long lifetime, small volume, good impact resistance, fast response and excellent stability. These characteristics have enabled the LEDs to be widely used as a light source in electrical appliances and electronic devices.

A conventional LED device includes a substrate, an LED packaging mounted on the substrate, and a light guiding plate facing and spaced from the LED packaging. Light emitted from the LED packaging travels through the LED packaging and radiates towards the light guiding plate. However, the light is prone to be totally reflected back into an interior of the LED packaging because the refractive index of the LED packaging is different from that of the air. Thus, a light extraction efficiency of the LED device is disadvantageously affected.

Accordingly, it is desirable to provide an LED device which can overcome the described limitations.

### BRIEF DESCRIPTION OF THE DRAWINGS

FIG. 1 is a cross sectional view of an LED device according to a first embodiment of the present disclosure.

FIG. 2 is a cross sectional view of an LED device according to a second embodiment of the present disclosure.

FIG. 3 is a cross sectional view of an LED device according to a third embodiment of the present disclosure.

FIG. 4 is a cross sectional view of an LED device according to a fourth embodiment of the present disclosure.

### DETAILED DESCRIPTION

Embodiments of LED devices will now be described in detail below and with reference to the drawings.

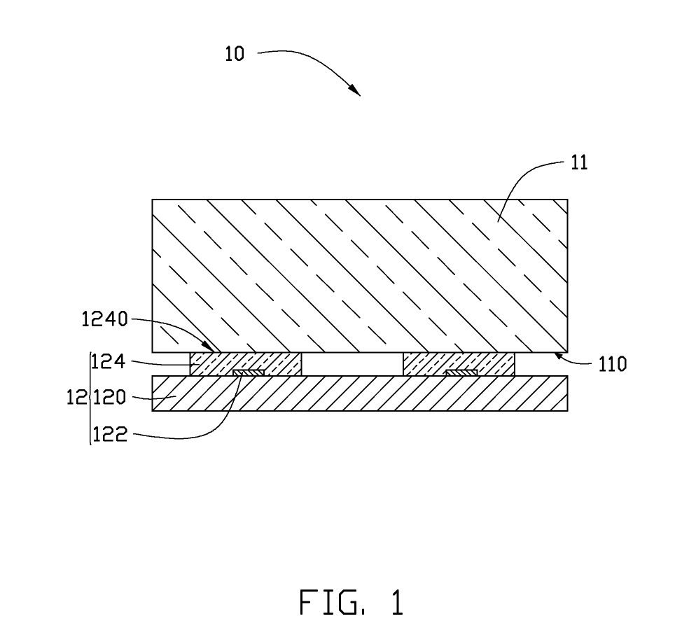

Referring to FIG. 1, an LED device 10 according to a first embodiment includes a light guiding member 11 and an LED light bar 12. The light guiding member 11 may be a light guiding plate, a lens, or a light dispersing plate. The light guiding member 11 has a light incident surface 110 for allowing light emitted from the LED light bar 12 travelling into the light guiding member 11 therefrom. The light incident surface 110 is flat.

The LED light bar 12 is arranged on the light incident surface 110 of the light guiding member 11. The LED light bar 12 includes a printed circuit board 120, a plurality of LEDs 122 mounted on a top surface of the printed circuit board 120, and a plurality of encapsulating layers 124 formed on the top surface of the printed circuit board 120 and respectively encapsulating the LEDs 122 therein. Each encapsulating layer 124 includes a light outputting surface 1240 facing the light incident surface 110. The encapsulating layer 124 is rectangular. The light outputting surface 1240 is flat. The light outputting surface 1240 is directly formed on the light incident surface 110 and firmly engages with the light incident surface 110. Air is entirely exhausted from a spaced between the incident surface 110 and the light outputting surfaces 1240. Thus, light emitted from the LEDs 122 travels through the light outputting surface 1240 of the encapsulating layer 124 and directly travels into the light guiding member 11 from the light incident surface 110.

When the refractive index of the light guiding member 11 is less than that of the encapsulating layer 124 and larger than that of the air, difference of the refractive index between the encapsulating layer 124 and the light guiding member 11 is less than that between the encapsulating layer 124 and the air. Therefore, the total reflection is avoided when the light travels through the light outputting surface 1240 and into the light guiding member 11 from the light incident surface 110. Thus, a light extraction efficiency of the LED device 10 is improved.

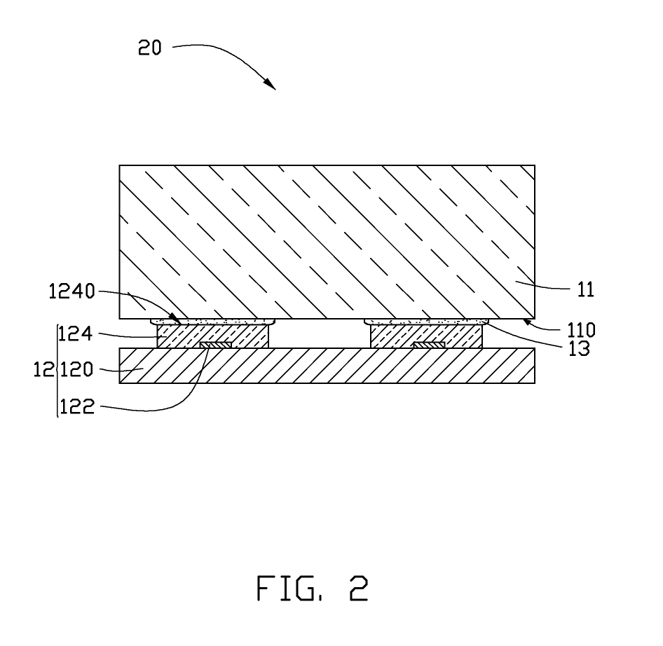

Referring to FIG. 2, an LED device 20 according to a second embodiment is shown. The LED device 20 is similar to the LED device 10 of the first embodiment, and difference between the LED device 20 and the LED device 10 is that a plurality of medium layers 13 is formed between the light guiding member 11 and the LED light bar 12 of the LED device 20. The medium layers 13 are respectively aligned with the encapsulating layers 124 and the LEDs 122. The medium layers 13 are spaced from each other. Each medium layer 13 is sandwiched between the light incident surface 110 and the light outputting surface 1240 of the corresponding encapsulating layer 124. Opposite sides of the medium layer 13 are directly and firmly adhered to the incident surface 110 and the light outputting surface 1240 to exhaust air between the incident surface 110 and the light outputting surface 1240.

In this embodiment, the medium layers 13 are located on light paths of the LEDs 122 and cover with radiation angles of the LEDs 122. Specifically, a size of each medium layer 13 is larger than that of the light outputting surface 1240 of the encapsulating layer 124. The light outputting surface 1240 is adhered on a central portion of the medium layer 13. The light outputting surface 1240 is entirely covered by the medium layer 13. A thickness of the medium layer 13 is not larger than 5 millimeters. Preferably, the thickness of the medium layer 13 is not larger than 0.1 millimeter.

In this embodiment, light emitted from the LEDs 122 travels through the encapsulating layers 124, the medium layers 13 and directly into the light guiding member 11. Compared with the conventional LED device, the refraction index of the medium layer 13 is larger than that of the air, difference of the refraction index between the encapsulating layer 124 and the medium layer 13 is less than that between the encapsulating layer 124 and the air. The encapsulating layer 124, the medium layer 13 and the light guiding member 11 are firmly and directly contact each other. Therefore, the total reflection is avoided when the light travels through the light outputting surface 1240 and into the medium layer 13. Thus, a light extraction efficiency of the LED device 20 is improved.

When the refraction index of the light guiding member 11 is not less than that of the encapsulating layer 124, the refraction index of the medium layer 13 is less than that of the encapsulating layer 124. Because the refraction index of the medium layer 13 is larger than that of the air, and the medium layer 13 exhausts air between the light incident surface 110 and the light outputting surface 1240, the total reflection is avoid when the light travels through the light outputting surface 1240 and into the medium layer 13. Alternatively, when the refraction index of the light guiding member 11 is not less than that of the encapsulating layer 124, the refraction index of the medium layer 13 is not less than that of the encapsulating layer 124 and less than that of the light guiding member 11, the total reflection is also avoided when the light travels through the light outputting surface 1240 and into the medium layer 13.

When the refraction index of the light guiding member 11 is less than that of the encapsulating layer 124, the refraction index of the medium layer 13 is larger than that of the light guiding member 11 and less than that of the encapsulating layer 124. In this state, the medium layer 13 is located between the light guiding member 11 and the encapsulating layer 124 to make the refraction index generally decrease from the encapsulating layer 124, the medium layer 13 to the light guiding member 11. Therefore, differences between the encapsulating layer 124 and the medium layer 13 and the medium layer 13 and the light guiding member 11 are generally reduced. Thus, the total reflection is also avoided when the light travels through the light outputting surface 1240 and into the medium layer 13. Alternatively, the refraction index of the medium layer 13 is larger than that of the encapsulating layer 124.

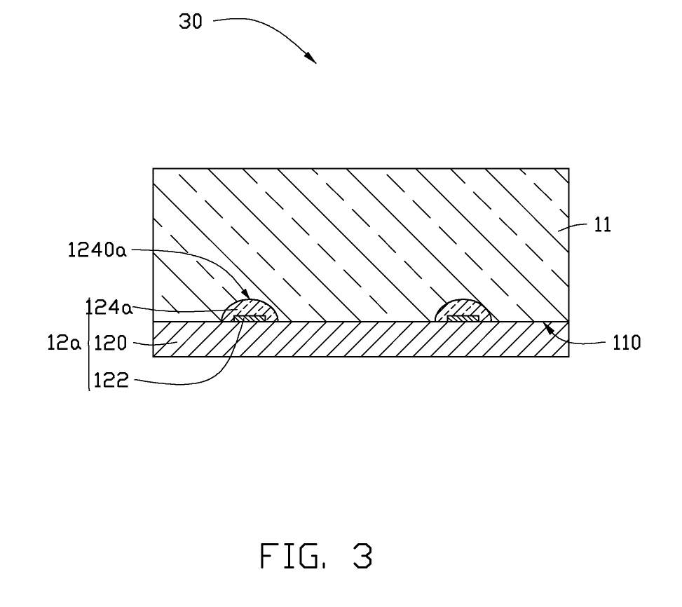

Referring to FIG. 3, an LED device 30 according to a third embodiment includes the light guiding 11 with the light incident surface 110 and an LED light bar 12a. The LED light bar 12a is similar to the LED light bar 12 of the first embodiment, the LED light bar 12a includes the printed circuit board 120 and a plurality of encapsulating layers 124a respectively encapsulating the LEDs 122 therein. The encapsulating layer 124a is a hemisphere and protrudes upwardly from the top surface of the printed circuit board 120. An outer surface of the encapsulating layer 124a is convex and functions as a light outputting surface 1240a. The geometrical center of the LED 122 is superposed to that of the corresponding encapsulating layer 124a. The light incident surface 110 of the light guiding member 11 is directly formed on the top surface of the printed circuit board 120. The encapsulating layers 124a and the LEDs 122 are received in the light guiding member 11. A bottom surface of each encapsulating layer 124a and bottom surfaces of the LEDs 122 are coplanar with the light incident surface 110. The light outputting surface 1240a firmly and directly contacts the light guiding member 11. Light emitted from the LEDs 122 travels through the light outputting surface 1240 and directly into the light guiding member 11 to avoid total reflection occurring the.

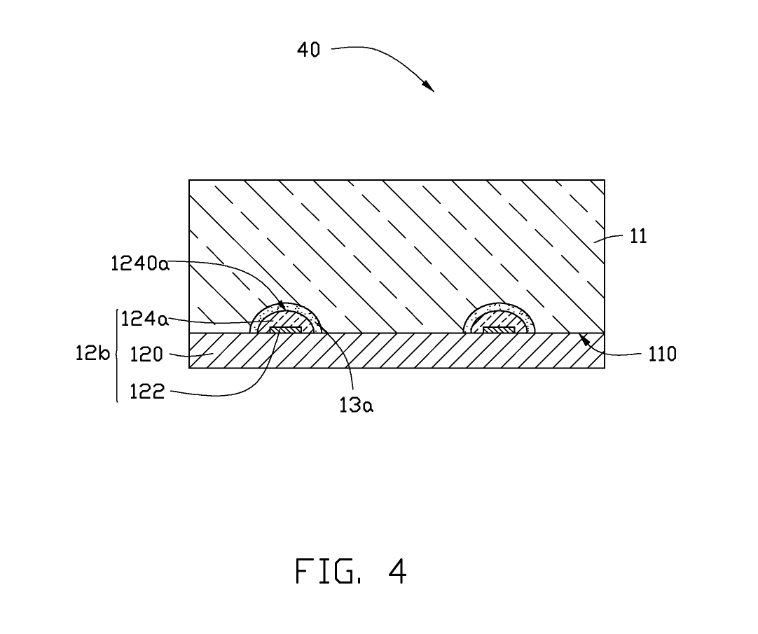

Referring to FIG. 4, an LED device 40 according to a fourth embodiment is shown. The LED device 40 is similar to the LED device 30 of the third embodiment except an LED light bar 12b. The LED light bar 12b of the LED device 40 includes the printed circuit board 120, the LEDs 122 formed on the printed circuit board 120, the encapsulating layers 124 encapsulating the LEDs 122 therein and received in the light guiding member 11, and a medium layer 13a formed on the light outputting surface 1240a and directly contacting the light guiding member 11. The medium layer 13a is used to fill in a small space between the light outputting surface 1240a and the light guiding member 11.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) device comprising:
a light guiding member having a light incident surface; and
an LED light bar mounted on the light incident surface, the LED light bar comprising a printed circuit board, a plurality of LEDs mounted on the printed circuit board, and a plurality of encapsulating layers formed on the printed circuit board and respectively encapsulating the LEDs therein, each encapsulating layer including a light outputting surface away from the printed circuit board;
wherein the light incident surface faces the light outputting surface and air between the light incident surface and the light outputting surface is entirely exhausted.

2. The LED device of claim 1, wherein the light outputting surface directly contacts the light guiding member.

3. The LED device of claim 2, wherein the light outputting surface is flat, located at a bottom end of the light incident surface and directly contacts the light incident surface.

4. The LED device of claim 2, wherein the encapsulating layer is hemisphere and received in the light guiding member, and an outer surface of the encapsulating layer is designated as the light outputting surface.

5. The LED device of claim 1, wherein a plurality of medium layers is formed between the light guiding member and the encapsulating layers, the medium layers are spaced from each other and respectively aligned with the encapsulating layers.

6. The LED device of claim 5, wherein the refraction index of the medium layer is less than that of the encapsulating layer.

7. The LED device of claim 5, wherein the refraction index of the medium layer is larger than that of the light guiding member.

8. The LED device of claim 5, wherein the medium layers are located on light paths of the LEDs and cover with radiation angles of the LEDs.

9. The LED device of claim 8, wherein a size of each medium layer is larger than that of the light outputting surface of the encapsulating layer, and the light outputting surface is adhered on a central portion of the medium layer.

10. The LED device of claim 5, wherein a thickness of the medium layer is not larger than 5 millimeters.

11. The LED device of claim 10, wherein the thickness of the medium layer is not larger than 0.1 millimeter.

12. The LED device of claim 5, wherein the light incident surface is located above the light outputting surfaces, the medium layers are sandwiched between the light incident surface and the light outputting surfaces, and opposite sides of the medium layer are directly and firmly adhered to the light incident surface and the light outputting surface.

13. The LED device of claim 12, wherein the light outputting surface is flat.

14. The LED device of claim 5, wherein the light incident surface contacts a top surface of the printed circuit board, and the encapsulating layers are received in the light guiding member.

15. The LED device of claim 14, wherein each medium layer is received in the light guiding member, and opposite sides of the medium layer respectively contact the light outputting surface and the light guiding member.

16. The LED device of claim 15, wherein the encapsulating layer is a hemisphere and protrudes upwardly from the top surface of the printed circuit board, and the light outputting surface is convex.

17. The LED device of claim 16, wherein the geometrical center of the LED is superposed to that of the encapsulating layer.
